(19) United States
(12) Patent Application Publication
(10) Pub. No.: US 2025/0220925 A1
(43) Pub. Date: Jul. 3, 2025

(54) THREE-DIMENSIONAL MEMORY ARCHITECTURES WITH HYBRID BONDING

(71) Applicant: Intel Corporation, Santa Clara, CA (US)

(72) Inventors: Adel Elsherbini, Chandler, AZ (US); Mudit Bhargava, Austin, TX (US); Kimin Jun, Portland, OR (US); Shawna M. Liff, Scottsdale, AZ (US)

(73) Assignee: Intel Corporation, Santa Clara, CA (US)

(21) Appl. No.: 18/397,513

(22) Filed: Dec. 27, 2023

(51) Int. Cl. H10B 80/00; H01L 23/00; H01L 25/00; H01L 25/065

(52) U.S. Cl. CPC H10B 80/00; H01L 24/05; H01L 24/08; H01L 24/80; H01L 25/0657; H01L 25/50; H01L 2224/0557; H01L 2224/05647; H01L 2224/08145; H01L 2224/80379; H01L 2224/80896; H01L 2225/06544; H01L 2924/0544; H01L 2924/059; H01L 2924/1437

(57) ABSTRACT

Three-dimensional (3D) memory architectures with hybrid bonding and methods for making same. Methods and apparatus employ ultra-high density (defined herein as sub 1 micron pitch) hybrid bond interface (HBI) stacking die/chiplets at the memory bank level. Various configurations for distributing the memory bank and the peripheral logic between a bottom die and a top die are described, with application to further die stacking. Provided apparatus may also implement dedicated vias for power delivery from a principle bottom die to the top die.

### BACKGROUND

The scaling of monolithic static random-access memory (SRAM) has not kept pace with the scaling of other standard cell logic components. However, since some chiplets can contain over 50% SRAM by area, improvements to SRAM density and integration with logic are desirable.

### BRIEF DESCRIPTION OF THE DRAWINGS

FIG. 1 is a schematic example of a SRAM in which the memory bit-line is split and stacked and implemented on two dies.

FIG. 2A illustrates a bit-line approach to splitting the SRAM circuitry among two dies.

FIG. 2B illustrates a word-line approach to splitting the SRAM circuitry among two dies.

FIG. 3 is a schematic illustration of a monolithic SRAM memory, for reference in various embodiments.

FIG. 4 illustrates an embodiment in which the memory bank of the SRAM memory is split into a bank on a top die and bank on a bottom die, and the periphery logic is kept on the bottom die.

FIG. 5 is a simplified cross-sectional image of a potential 3D construction of the embodiment of FIG. 4.

FIG. 6 illustrates an exemplary manufacturing flow for a three-dimensional memory architecture with hybrid bonding, in accordance with embodiments described herein.

FIG. 7 illustrates additional embodiments in which the memory bank of the SRAM memory is split into a bank on a top die and bank on a bottom die, and also proposing alternatives for splitting the periphery logic between the bottom die and top die.

FIG. 8A and FIG. 8B are simplified cross-sectional images of potential 3D constructions for the embodiments of FIG. 7.

FIG. 9 illustrates another exemplary embodiment, in which the memory bank is kept together on a top die and the periphery logic is kept on the bottom die.

FIG. 10 is a top view of a wafer and dies that may be included in any of the embodiments disclosed herein.

FIG. 11 is a simplified cross-sectional side view showing an implementation of an integrated circuit on a die that may be included in any of the embodiments disclosed herein.

FIG. 12A-12D are simplified perspective views of example planar, FinFET, gate-all-around, and stacked gate-all-around transistors, as may be implemented in various embodiments.

FIG. 13 is a cross-sectional side view of a microelectronic assembly that may include any of the embodiments disclosed herein.

FIG. 14 is a block diagram of an example electrical device that may include any of the embodiments disclosed herein.

### DETAILED DESCRIPTION

The scaling of monolithic static random-access memory (SRAM), which is used in cache memory and other applications, has not kept pace with the scaling of other standard cell logic components. This scaling difference is at least partly due to the SRAM cell having some vulnerabilities to shrinking that other standard cell logic components do not have. As used herein, integrated circuit dies can include logic and/or memory and can be referred to as “chiplets.” Some chiplets, such as processor chiplets, can contain over 50% SRAM by area; therefore, it is desirable to improve the SRAM/cache performance, density, and integration with logic.

One available technical solution disaggregates the monolithic memory into memory chiplets and stacks the memory chiplets to achieve the original memory density. For example, multiple SRAM chiplets can be stacked to form SRAM memory “cubes.” This approach improves the memory density per square millimeter, but it suffers from several draw backs such as: (1) the total cost/Mb is increasing due to the added stacking costs, (2) although shorter on-chip routing may improve the overall latency, the single bank performance is still identical to that of the monolithic memory, and (3) the added overhead, such as the added through silicon vias (TSVs) adds area, adversely impacts the power delivery, and the redundancy can further offset the benefits of this approach.

Another technical solution is to layer or stack memory and logic, sometimes called memory under/over logic. This can improve density and integration of chiplets, but it doesn't improve the intrinsic performance or capability of the memory component.

Embodiments disclosed herein propose a technical solution to the above-described technical problems in the form of three-dimensional (3D) memory architectures with hybrid bonding. Methods and apparatus introduce ultra-high density (defined herein as sub 1 micron pitch) hybrid bond interface (HBI) stacking die/chiplets at the memory bank level. Embodiments make use of the very fine pitch capability of hybrid bonding to connect die/chiplets or even wafers at the bit-line level. Embodiments also implement dedicated vias for power delivery from a principle bottom die to the top die. The dedicated power delivery vias are sometimes referred to herein as “power vias”. These concepts are developed in more detail below.

Embodiments can be recognized using SEM images focused on a cross-sectional area where the bit-line/word-line connections between the different tiers of memory are located and identify the herein described hybrid bonded architectures, in combination with the placement of the memory bank and peripheral logic, as described below. Additionally, embodiments can be recognized in SEM images by locating the herein described power via power delivery solution for the top die.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

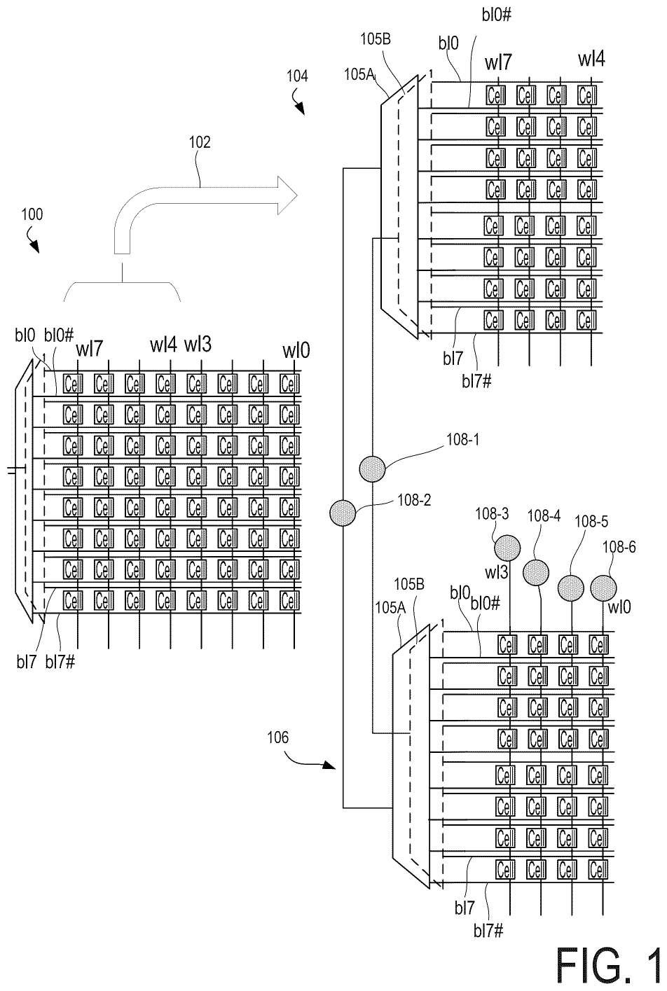

FIG. 1 is a schematic example embodiment 100 of a SRAM in which the memory bank is split, and the memory bit-line is split and stacked and implemented on two dies. On the left of the page, eight word-lines are illustrated (wl7-wl0) and eight sets of bit-line/bit-line # are illustrated (bl0/bl0 #-bl7/bl7 #). The associated SRAM memory cells are indicated with “cell.” Cartoon arrow 102 shows that a portion of the cells with the bit-lines and half of the word-lines (wl7-wl4) is moved to a second die 104 (e.g., the top die). Meanwhile, the cells associated with the first four word-lines (wl0-wl3) and the bit-lines remain on the first die 106 or base die. In this configuration, the bit-lines 108-1 and 108-2 and word-lines (108-3, 108-4, 108-5, and 108-6) are reconnected after the bit-line multiplexer 105A, 105B to enable reduced bit-line capacitance.

Hybrid bonding (also, HB, and HBI) is referenced herein. Hybrid bonding, also called direct bond interconnect (DBI) is a packaging technology that involves bringing together the surfaces of two semiconductor devices under applied pressure and/or at elevated temperature, generally as a die stacking solution, resulting in dielectric-to-dielectric bonding and metal-to-metal bonding (without solder and without underfill). HBI advantageously enables “small” pitches (defined herein as a pitch less than 10 microns+/−20%, and in some cases, the pitch is less than 1 micron+/−20%) between neighboring conductive contacts.

In a generalized example, a first semiconductor die is fabricated with layers of insulating material or dielectric material and/or oxides, interspersed with conductive interconnects (vias and traces), building up to a hybrid bond (HB) surface. At least one hybrid bond conductive contact (sometime called a HB pad) is exposed at the HB surface. Likewise, a second die is similarly constructed and has a second HB surface with at least one corresponding HB conductive contact. The HB conductive contacts (shortened herein to conductive contacts) are conductive, generally comprising a metal, such as copper (Cu). In some embodiments, the HB conductive contacts may include one or more of gold, tungsten, aluminum, titanium, tantalum, molybdenum, magnesium, and cobalt (W, Mo, Ti, Au, Mg, Ta, Co, Al) or tertiary systems or designer grain systems.

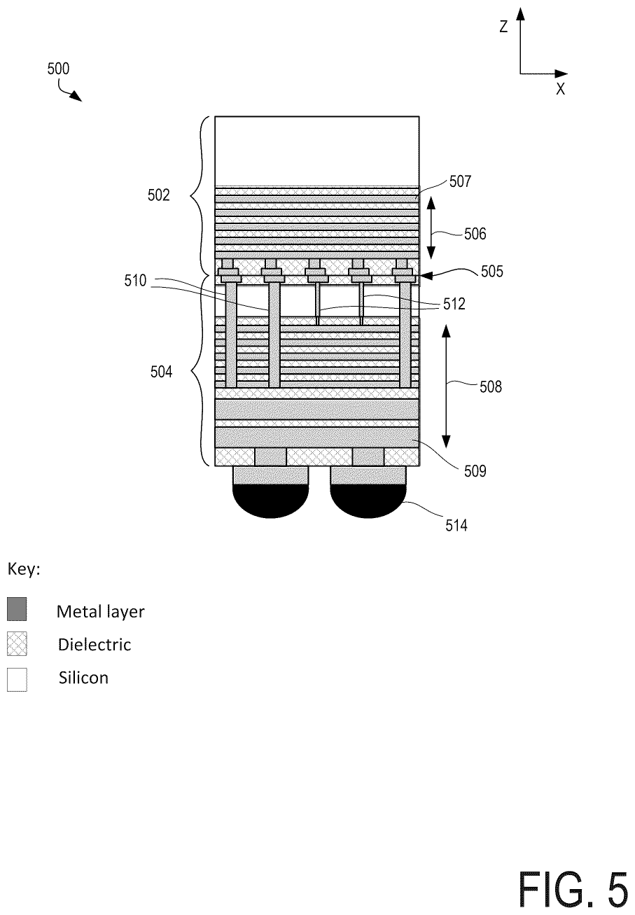

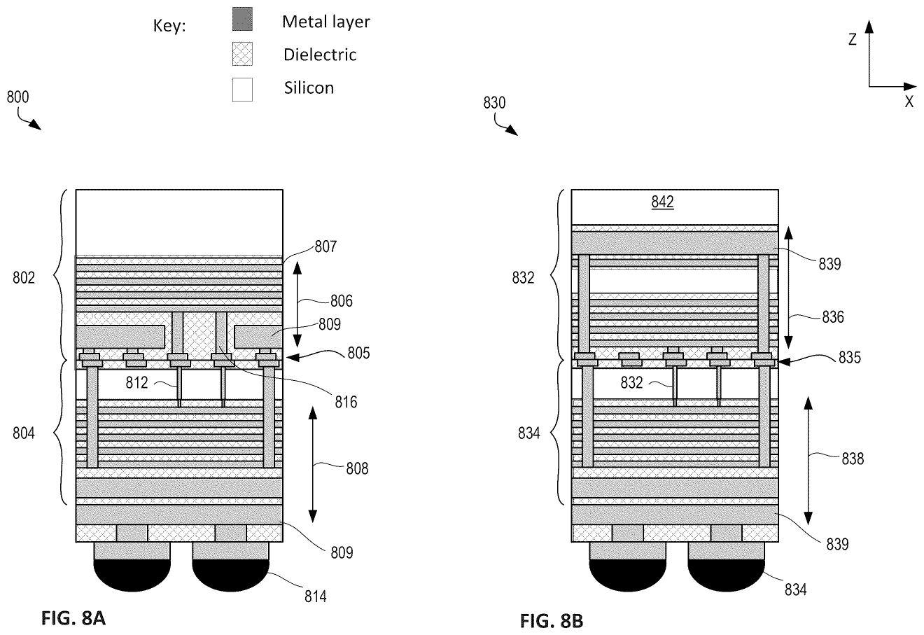

The conductive contacts are surrounded by (in a plan view at their respective HB surface) the insulating or dielectric material. In other words, there is dielectric material adjacent to metal/Cu contacts. When the first die is described as hybrid bonded to the second die, what is seen in a SEM image is an HB interface (e.g., FIG. 5, HB interface 505, and FIGS. 8A, 8B, HB interfaces 805 and 835), characterized by insulating or dielectric material of the first die bonded directly to the insulating or dielectric material of the second die (e.g., SiOx to SiOx, SiOxNy to SiOxNy, intralevel dielectric insulator (ILD), ultra-low dielectric constant (ultra-low k) dielectric, or the like) and conductive contacts from the first die are direct metal bonded to respective conductive contacts of the second die, and there is no solder material, no underfill, at the HB interface. In most applications, at least one HB conductive contact is coupled to the integrated circuitry of a chiplet region or active region in the first or second die, e.g., via a through silicon via (TSV) or through dielectric via (TDV). In various aspects of the disclosure, the HB conductive contacts are to provide an electrical path from respective nodes in the chiplet regions through the bonding layers and are exposed at the HB surface(s).

One of the advantages of the stacking illustrated in embodiment 100 is that it can take advantage of the pitch that can be achieved with the hybrid bond interconnect (HBI) to improve the memory and system performance and cost. However, this requires much finer pitch, e.g., less than 0.1 microns (plus or minus 20%), whereas the memory stacking architectures used in other solutions may require very fine pitch but do not offer the same performance or cost benefits. As the HBI technology scales, it is expected to continue to scale and support finer pitches in the future.

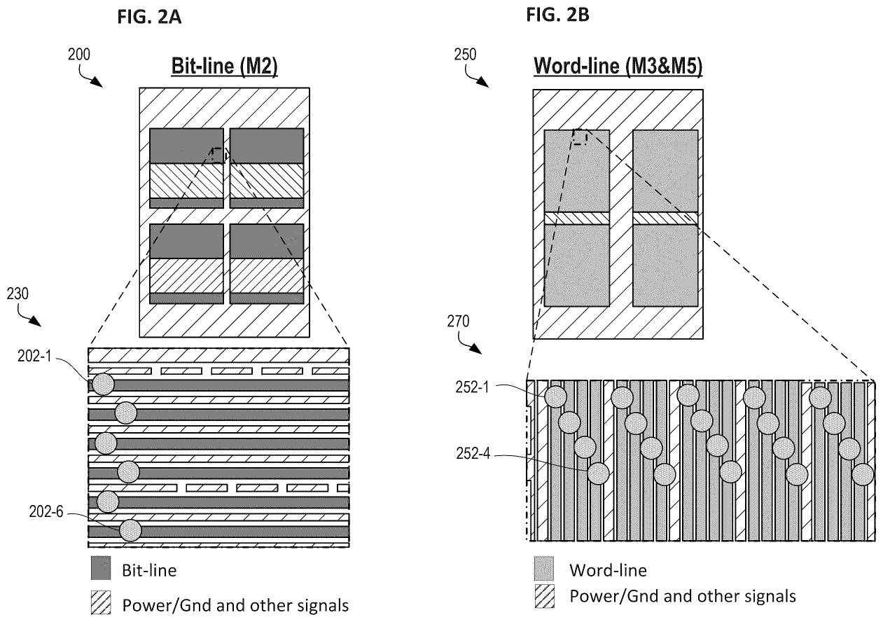

Additionally, in various embodiments, the HB bump floor-planning can be varied to support a proposed three-dimensional (3D) stacking approach. In FIG. 2A, embodiment 200 illustrates a bit-line approach, as may be implemented, for example, using a metal layer such as metal 2 (M2). As shown in the expanded region 230, the HB conductive contacts or HB pads 202-1 to 202-6 are staggered over the (horizontally illustrated) bit-lines to reduce the pitch requirements. Power, ground, and other signals may be routed in between bit lines, as illustrated with the diagonal lined tracing. In FIG. 2B, embodiment 250 illustrates a word-line approach, as may be implemented, for example, in metal layers such as metal 3 and metal 5 (M3 & M5). As shown in the expanded region 270, the HB conductive contacts or HB pads 252-1 to 252-4 are staggered over the (vertically illustrated) word-lines and repeated in sets from left to right, to reduce the pitch requirements. Again, the power, ground, and other signals may be routed in-between the word-lines, as illustrated with the diagonal lined regions.

The embodiments illustrated in FIG. 2A and FIG. 2B are non-limiting. Depending on the hybrid bonding technology used, the HB conductive contacts may not need to be staggered. Additionally, other embodiments can implement encoding, or partial encoding before the HB conductive contacts, to minimize the number of signals (e.g., power, ground, and control signals) across the HB interface and further relax the pitch requirements. However, in some scenarios, the relaxed pitch requirements may come at the expense of slightly higher power and/or design complexity, so these considerations are to be balanced for different applications. These concepts are developed further in the following description.

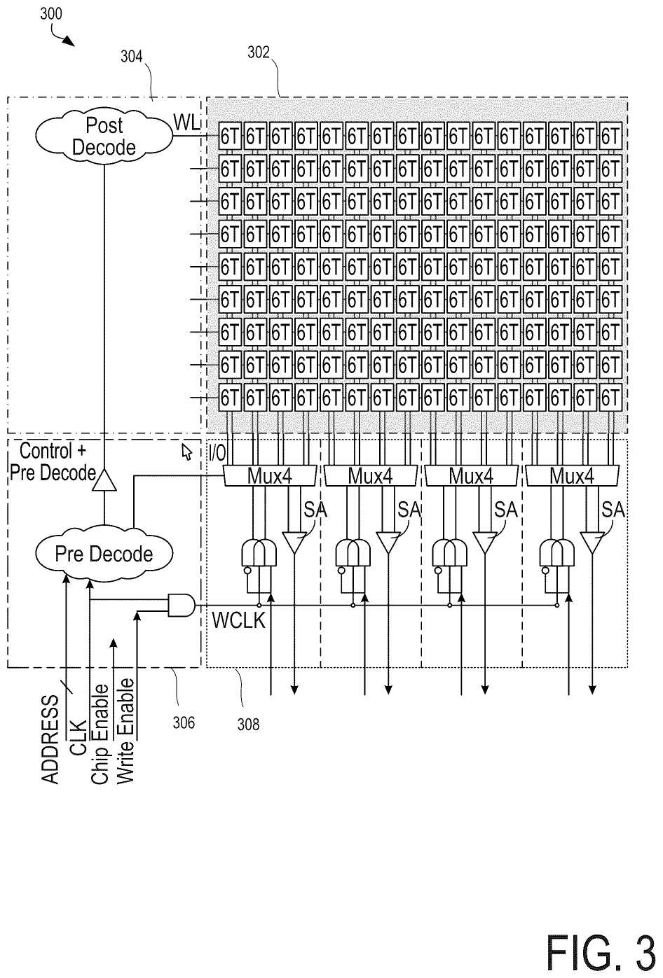

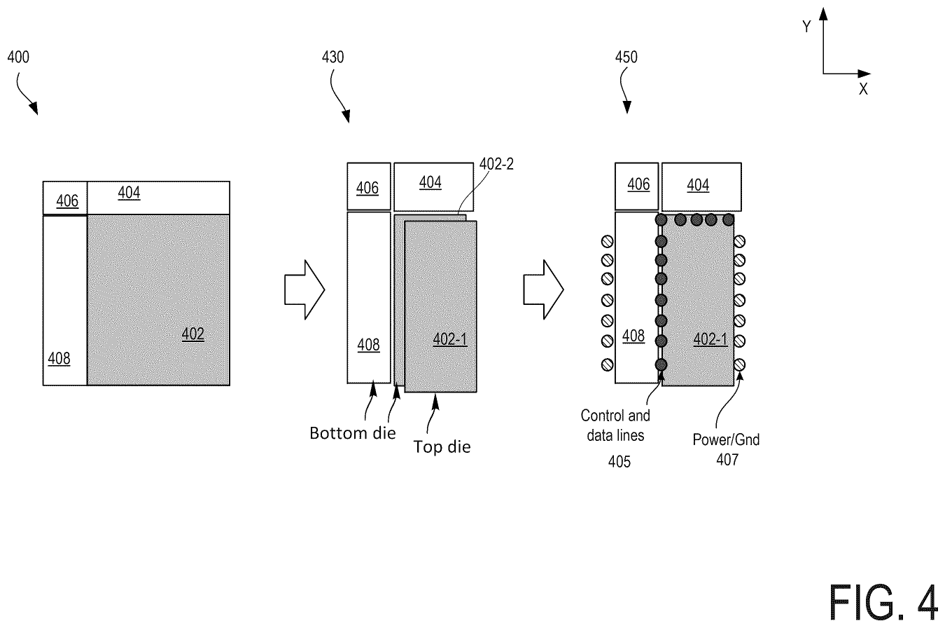

FIG. 3 is a schematic illustration of a monolithic SRAM memory 300, as may be recognized by those with skill in the art, and is referenced in the discussion of the proposed circuit split arrangements illustrated in FIGS. 4, 5, 7, 8, and 9. The embodiments proposed in FIGS. 4, 5, 7, 8, and 9 include different circuit split arrangements and different 3D manufacturing technologies to support their requirements, such as the connection density, and routing and power delivery requirements. The memory bank 302 portion comprises an array of six transistor cells (“6T”), having attached thereto word-lines (WL) and the bit-line/bit-line # pairs described above. The control and pre-decode circuitry 306 block drives the post-decode circuitry 304 block and the bit-line circuitry 308. The memory bank 302 (memory bank 402, memory bank 702, memory bank 902) is shaded gray to be consistent with the illustrations in FIGS. 4-9. Collectively, the control and pre-decode circuitry 306/406/706/906 block, the post-decode circuitry 304/404/704/904 block, and the bit-line circuitry 308/408/708/908 block may be referred to as “peripheral logic” or “peripheral circuitry.”

In a first non-limiting example detailed in FIG. 4, a monolithic SRAM 400 is illustrated in which the memory bank 402 is split or divided into memory sub-bank 402-1 on a top die and memory sub-bank 402-2 on a base/bottom die, and the periphery logic is kept on the bottom die. This is illustrated in SRAM embodiment 430 and SRAM embodiment 450. The periphery logic is typically the high-power component in a memory bank, and thus keeping it all on the base/bottom die can help reduce the power delivery requirements to the top die. The SRAM 400 includes control and data lines 405 (sometimes referred to as signal pads 405) and power lines and power pads (sometimes shortened to power pads 407), As illustrated with SRAM embodiment 450, the control and data lines 405 can connect at the periphery of the memory sub-banks (402-1 and 402-2) and the power lines and power pads 407 will connect mostly outside the periphery circuits to avoid density limitations due to TSVs.

The split arrangement embodiment 450 illustrated in FIG. 4 can advantageously result in shorter bit-lines, which deliver a performance improvement. However, this split arrangement can result in lower bank density improvements compared to other split arrangements.

FIG. 5 is a simplified cross-sectional image 500 of a potential 3D construction of the embodiment 450. In this configuration, the top die 502 contains only bit cells, and is thus low power. This embodiment enables a much shorter metal stack 506 (i.e., the thickness in the Z direction is less than the thickness of the metal stack 508 from the base or bottom die 504) and can utilize thinner metal layers 507 in the metal stack 506 than some of the metal layers 509 in the bottom die metal stack 508. As used herein, the metal stack is a region of the die in which multiple layers of metal are interleaved with insulating layers or dielectric layers. In some scenarios, the stack comprises six layers of metal. As used herein, a thick layer of metal is greater than 500 nanometers in the Z direction+/−20% in the illustrations and a thin layer of metal is less than 200 nanometers+/−20% in the Z direction in the. Metal layers are depicted in gray, the dielectric is in a hatched pattern, and silicon is white. The bottom surface may have solder bumps 514, e.g. to attach to a solder silicon interposer or to an organic package or may have other hybrid bonding bumps to attach to other memory stack to form multiple stacks or a hybrid bonding interposer to connect to a neighboring die, e.g., a CPU or GPU.

There are several types of through-connections in this embodiment. A “TSV middle” (TSVs 510) is so named because the TSVs 510 are created after the first few metal layers are deposited. In contrast, a “TSV first” (TSVs 512) is a through silicon via created in the silicon before the next level metallization is available. When the TSV first through-connections are implemented, they are generally filled with a metal such as tungsten or another front end of line (FEOL) compatible metal. The TSVs 510 of the TSV middle approach enable lower resistance through the metal stack 508 but can result in added routing blockages to accommodate larger keep out zones (KoZ). The TSVs 512 (“TSV first”) can have a much smaller KoZ than the TSV middles, because they do not have to support efficient power delivery; however, in some embodiments, they are as large as the TSV middles. In a non-limiting example, the TSV first (TSV 512) critical dimension diameter (CD) is between 0.01 (+/−20%) micron to 10 microns (+/−20%) or more, and the TSV middle (TSV 510) have a CD of 0.5 micron (+/−20%) to 10 microns (+/−20%). In an embodiment, the TSV first has a minimum critical dimension less than 10 microns+/−20%. In some embodiments, some conductive contacts are attached to TSVs with a minimum critical dimension greater than 1 micron+/−20%.

The two TSV options may also be combined, e.g., the TSV first may be used for within bank signals where the KoZ and pitch may be more important and the TSV middle approach may be used for power where the resistance is more important or signal connections to the other dies on the package. In various aspects of the disclosure, the TSVs (510 and 512) have a liner, for example, a silicon dioxide (SiO₂) coating of a specific thickness inside the interior of the TSV. This liner can be used to tune the capacitance for the signal associated with the TSV, as a function of the silicon resistivity, the TSV length, and the TSV CD; however, for a power TSV, tuning capacitance is less important, and the liner is used more as a stress buffer and to enhance surface adhesion. Accordingly, the CD and the liner thickness among TSVs (510 and 512) in a product can differ dependent upon whether the intent is to optimize power or to optimize high-speed signal performance.

Alternatively, the TSV first 512 could be replaced with a “TSV last” process, meaning that it is completed after reveal and before hybrid bonding is enabled, to avoid the presence of buried metal in the FEOL process.

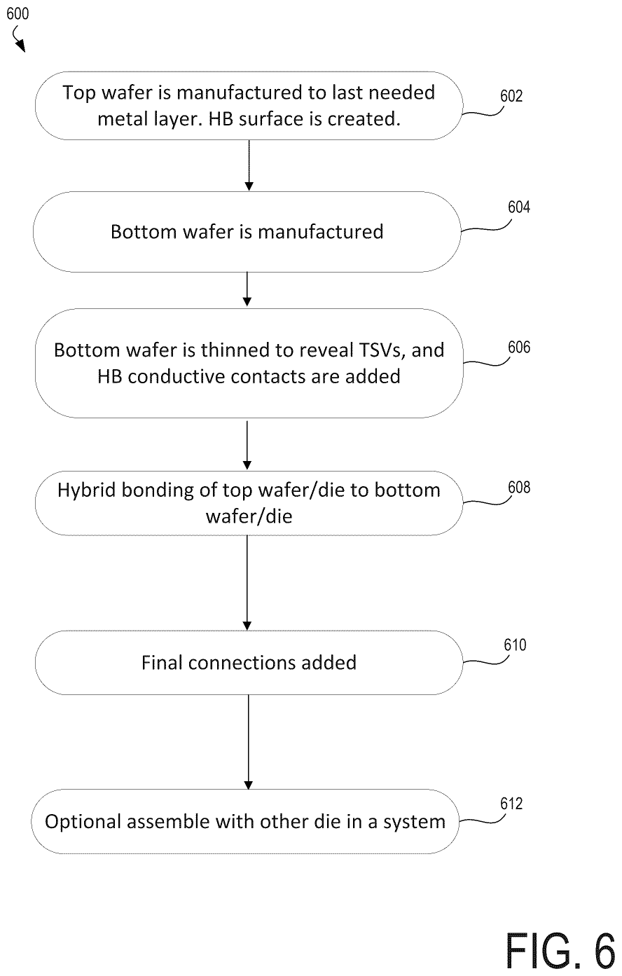

FIG. 6 illustrates an exemplary manufacturing flow 600 for a three-dimensional memory architecture with hybrid bonding, in accordance with embodiments described herein. At 602, the top wafer or top die 502 is manufactured up to the last needed metal layer (e.g., metal stack 506 includes up to M5 or M6) then a hybrid bonding surface is created on the top wafer or top die 502. As described above, the HB surface includes insulator/dielectric material and vias plus conductive contacts, or insulator/dielectric material and conductive contacts (i.e., and no vias). In some scenarios, the HB surface may also be used for partial routing and may contain conductive traces.

At 604, the bottom wafer or bottom die 504 is manufactured. At 604 the following tasks may be performed: (a) the devices that comprise the integrated circuit and/or periphery logic for a SRAM die on the bottom wafer are created, then any TSV first interconnects (TSVs 512) are created, (b) the next few metal layers are created with keep out zones to support any to-be-created TSV middle interconnects (TSVs 510), (c) The TSV middles are created, and (d) the topmost metal layer(s) in the metal stack 508 are created. The TSV first interconnects (TSVs 512) can have a pitch on the order of 50 nanometers (nm) (+/−20%) to 500 nm (+/−20%) when used for carrying control and data signals from memory sub-bank to memory sub-bank. In contrast, the TSV middle interconnects (TSVs 510) have a larger pitch, such as, in a range of 100 microns (um) to 500 um, when used to carry power and ground signals. Either the TSVs 510, or the TSVs 512, or a combination thereof, can be to carry control and data signals from the memory bank to other logic, such as to a CPU.

At 606, the bottom wafer 504 is thinned to reveal the TSVs 510/512 then the hybrid bonding pads (referred to hereinabove as conductive contacts) are created. Note alternatively, after reveal and prior to hybrid bonding, the signal vias may instead be added through the aforementioned TSV last process.

At 608, the top wafer 502 and the bottom wafer 504 are bonded, creating the HB interface 505, as described above. Bonding is direct, wafer to wafer bonding, dielectric to dielectric and metal to metal, without underfill or solder, as described above. Alternatively, at 608, the two wafers may be singulated into individual dies, and the respective individual dies are hybrid bonded. Singulating the die first may be more suitable for performance matching and/or to avoid cumulative yield issues.

At 610, the final connections (e.g., the bottom solder bumps) may be created, completing the SRAM bank apparatus, and at 612 the SRAM bank apparatus is attached to the rest of the system (e.g., through direct stacking to a processor chiplet or through a passive interposer to a processor chiplet).

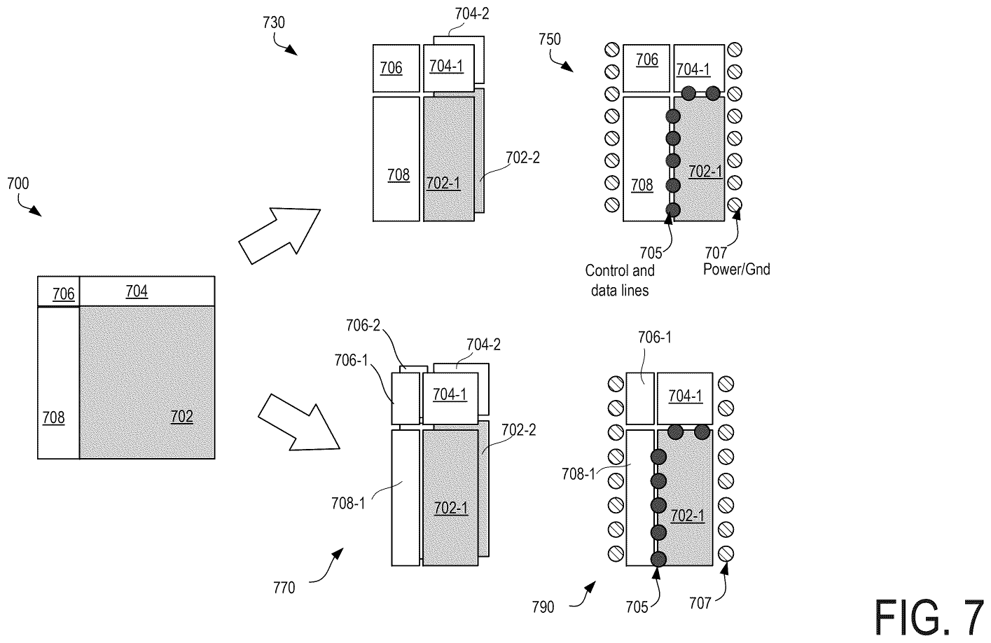

FIGS. 7-9 provide additional embodiments that can be manufactured in a similar process flow.

In FIG. 7 two additional ways to split the monolithic SRAM 700 are depicted. On the top of the page, embodiments 730 and 750 illustrate splitting the memory cell bank 702 into two, bank 702-1 on a top die and bank 702-2 on a base/bottom die. In addition, these embodiments split some of the periphery logic, for example, in embodiments 730 and 750, the post-decode circuitry 704 block is split into a top die 704-1 and bottom die 704-2. The embodiments 770 and 790 on the lower part of the page go even further. In addition to splitting the memory cell bank 702 and the post-decode circuitry 704, the remainder of the periphery logic/periphery circuitry can be split among the top die and the bottom die, as illustrated with the control and pre-decode circuitry 706-1/706-2, and the bit-line circuitry 708-1/708-2.

The embodiments illustrated in FIG. 7 can improve the area efficiency of an SRAM apparatus (meaning that the overall area for the SRAM apparatus is reduced/smaller using these configurations as compared to implementing the monolithic SRAM). The area efficiency is improved since the periphery logic is also split between the two dies. However, because these embodiments implement logic circuits (periphery logic) in both tiers or die in addition to memory cells, a manufacturing flow that is utilized for each wafer may sacrifice some technology optimization (for memory cell or for logic). Additionally, these embodiments implement two high-power tiers, one on the bottom die and one on the top die, and both high-power tiers need power delivery support, which provides its own technical challenge. Furthermore, it may not be desirable to perforate the peripheral circuits with TSVs since there is generally dense routing in the peripheral circuits area already.

FIG. 8A is a simplified cross-sectional image 800 of a potential 3D construction of the embodiment 750. FIG. 8B is a simplified cross-sectional image of an embodiment 830 of potential 3D construction of the embodiment 790. In these configurations, the top die 802/832 contains bit cells and some periphery logic. The periphery logic imposes a need for at least one thick metal layer 809/839 in the top die 802/832. Note that the presence of at least one thick metal layer 809/839 increases the thickness of the metal stack 806/836. In FIG. 8A, the thick metal layer 809 is deposited closer to the HB surface of the top die 802 and hence closer to the HB interface 805.

Often, the thick metal layers 809/839 cannot support the very fine pitch needed for connecting to the word-lines/bit-lines. To address that, introduce a new through-connection, sometimes referred to as a super via (TSV 816) the super vias TSV 816 land on and connect directly to the metal layer immediately below it. The super vias TSV 816 perforate the thick metal layer 809, with its associated KoZ, as it carries a signal upward into the metal stack 806.

In FIG. 8A and FIG. 8B, the bottom die 804/834 has similar construction to bottom die 504, with metal stack 808/838 including at least one thick metal layer 809/839, dielectric or insulating material (shown hatched) between metal layers in the metal stack, and silicon at the HB surface. Conductive contacts and TSVs 812/832 are exposed at the HB surface that coincides with the HB interface 805/835, as described above. The bottom surface may have solder bumps 814/834.

Alternatively, as shown in FIG. 8B, the power delivery metal layer (thick metal layer 839) can be fabricated on the backside of the top die 832, to enable the required power distribution without the need for the above described super vias TSV 816. Note in this case the silicon thickness in some embodiments may be thicker, such as, greater than 10.5 microns (+/−20%), to harness the bulk thermal spreading capability of silicon; at thinner silicon thicknesses, the thermal spreading capability drops exponentially, risking device overheating. As illustrated, the top die 832 has a thicker metal stack 836 than the metal stack 806, or the metal stack 406 (i.e., the thickness measured in the Z direction is greater than the thickness of the metal stack 806 and greater than the thickness of the metal stack 406) because it implements at least one thick metal layer 839 for power distribution near the top of the metal stack 836. This configuration/embodiment 830 can reduce the perforations in the thick metal layers 839 in the top die 832 but can bring added thickness with at least one layer of silicon 842 in between metal layers in the metal stack 836. As before, the metal layers are depicted in gray, the dielectric is in a hatched pattern, and silicon is white.

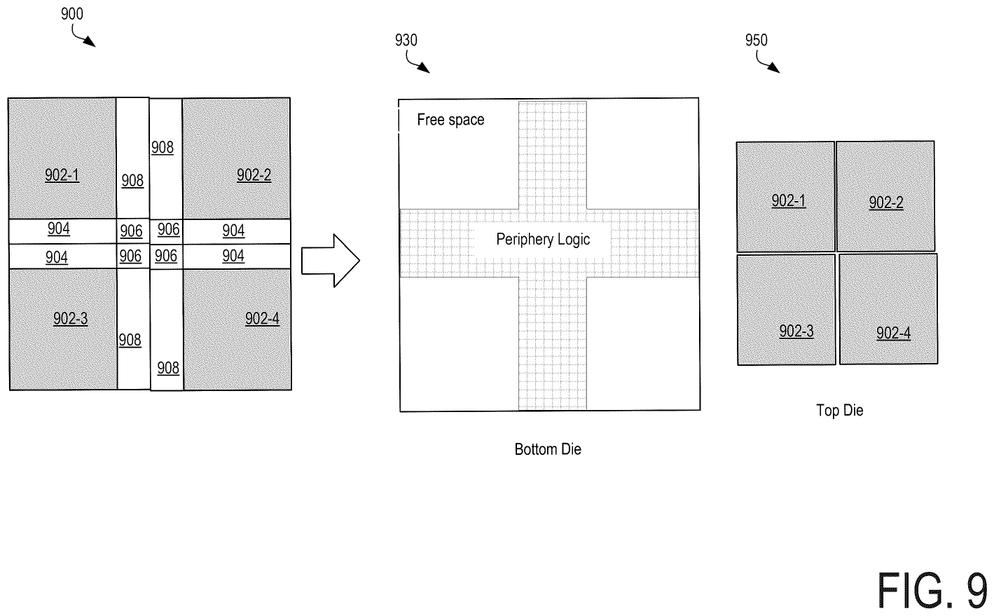

FIG. 9 depicts another proposed embodiment. In this embodiment, the monolithic SRAM 900 is split such that the top die 950 comprises bit cells only, and the bottom die 930 comprises only periphery logic. This enables the manufacturer to optimize each tier, using an optimized bit cell technology for the top die and an optimized logic technology for the bottom die. The periphery circuits are usually 20-30% of the total area, and thus this embodiment can have empty space on the base die. This empty space may be utilized by other system components such as processing elements or e.g., in-memory compute logic.

Thus, three-dimensional (3D) memory architectures with hybrid bonding have been introduced. Methods and apparatus employ ultra-high density (defined herein as sub 1 micron pitch) hybrid bond interface (HBI) stacking die/chiplets at the memory bank level and make use of the very fine pitch capability of hybrid bonding to connect die/chiplets or even wafers at the bit-line and/or word-line level. Some embodiments also implement dedicated vias for power delivery from a principle bottom die to the top die.

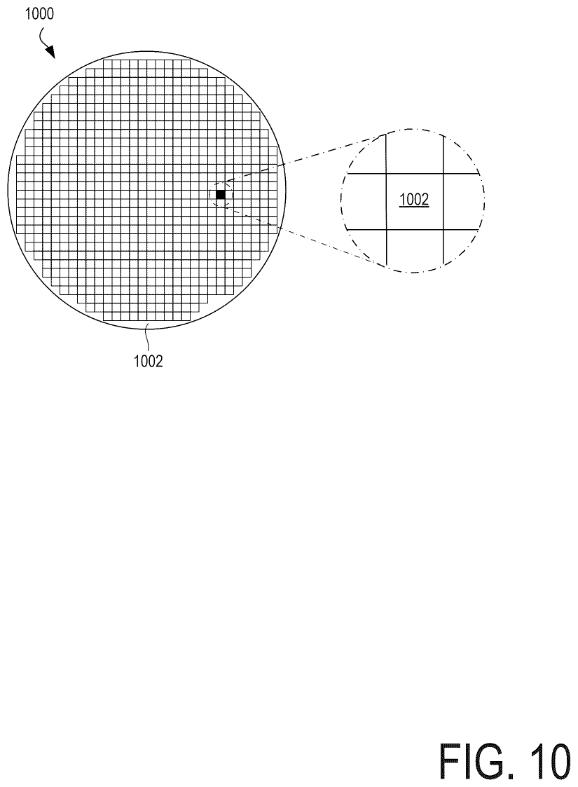

To enable even higher densities, two types of further stacking are possible. A first method is to continue the bit-cell/periphery stacking described above, e.g., multiple layers of bit-cells only or combined bit-cells and periphery. Another method is to employ system level stacking, in which each bit-cell stacked chiplet is treated as a monolithic SRAM chiplet, and the standard system-level SRAM stacking architecture is used (e.g., through on-chip routing to the center and having system level data/address TSVs there). In other embodiments, multi-layer SRAM stacks may be implemented. For example, trench capacitors, and deep trench capacitors. Moreover, the examples and embodiments described above may include, or be included in, embodiments described in connection with FIGS. 10-14.

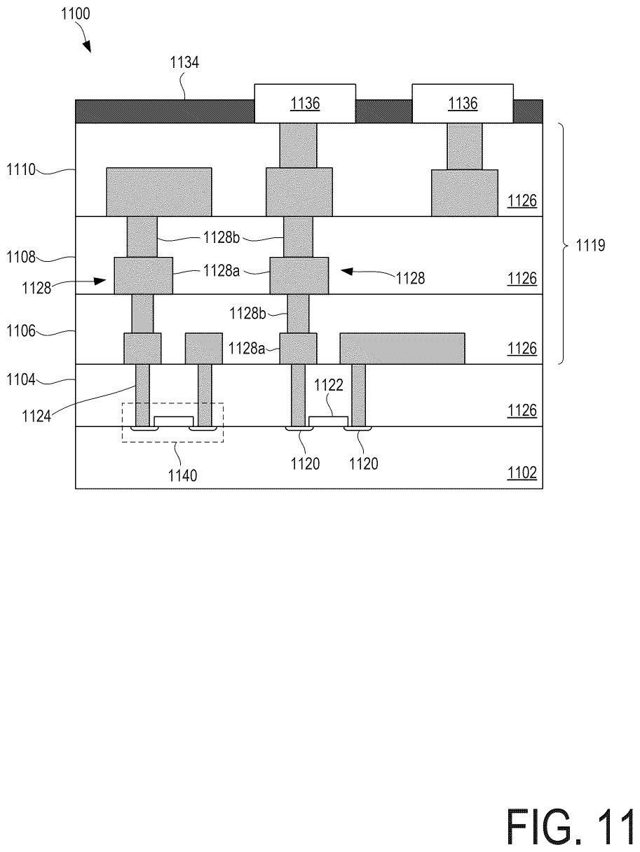

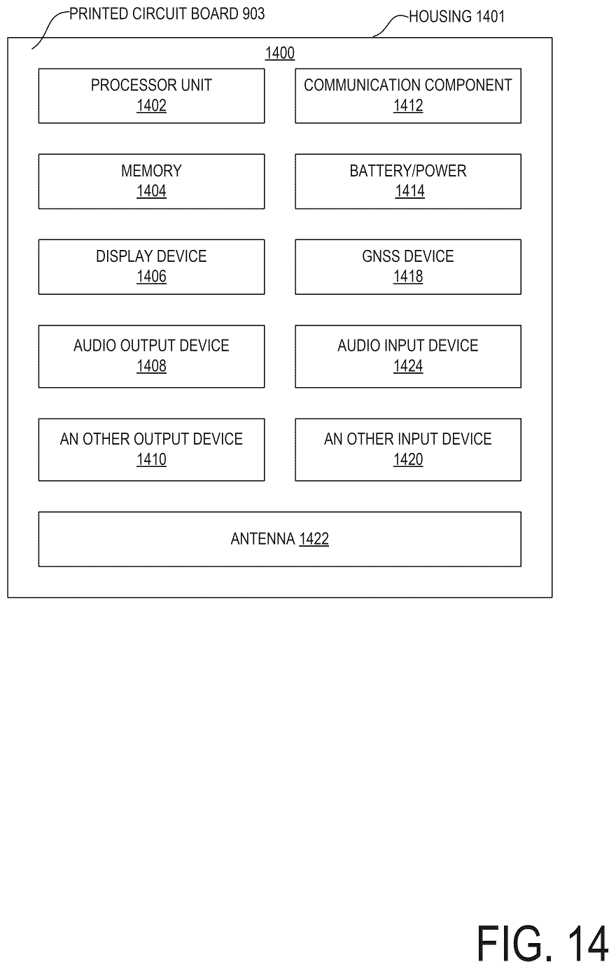

FIG. 10 is a top view of a wafer 1000 and dies 1002 that may be included in any of the embodiments disclosed herein. The wafer 1000 may be composed of semiconductor material and may include one or more dies 1002 formed on a surface of the wafer 1000. After the fabrication of the integrated circuit components on the wafer 1000 is complete, the wafer 1000 may undergo a singulation process in which the dies 1002 are separated from one another to provide discrete “chips” or destined for a packaged integrated circuit component. The individual dies 1002, comprising an integrated circuit component, may include one or more transistors (e.g., some of the transistors 1140 of FIG. 11, discussed below), supporting circuitry to route electrical signals to the transistors, passive components (e.g., signal traces, resistors, capacitors, or inductors), and/or any other integrated circuit components. In some embodiments, the wafer 1000 or the die 1002 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 1002. For example, a memory array formed by multiple memory devices may be formed on a same die 1002 as a processor unit (e.g., the processor unit 1402 of FIG. 14) or other logic that is configured to store information in the memory devices or execute instructions stored in the memory array. In some embodiments, a die 1002 may be attached to a wafer 1000 that includes other die, and the wafer 1000 is subsequently singulated, this manufacturing procedure is referred to as a die-to-wafer assembly technique.

FIG. 11 is a cross-sectional side view of an integrated circuit 1100 that may be included in any of the embodiments disclosed herein. One or more of the integrated circuits 1100 may be included in one or more dies 1002 (FIG. 10). The integrated circuit 1100 may be formed on a die substrate 1102 (e.g., the wafer 1000 of FIG. 10) and may be included in a die (e.g., the die 1002 of FIG. 10).

The die substrate 1102 may be a semiconductor substrate composed of semiconductor material systems including, for example, n-type or p-type materials systems (or a combination of both). The die substrate 1102 may include, for example, a crystalline substrate formed using a bulk silicon or a silicon-on-insulator (SOI) substructure. In some embodiments, the die substrate 1102 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1102. Although a few examples of materials from which the die substrate 1102 may be formed are described here, any material that may serve as a foundation for an integrated circuit 1100 may be used. The die substrate 1102 may be part of a singulated die (e.g., the dies 1002 of FIG. 10) or a wafer (e.g., the wafer 1000 of FIG. 10).

The integrated circuit 1100 may include one or more device layers 1104 disposed on the die substrate 1102. The device layer 1104 may include features of one or more transistors 1140 (e.g., metal oxide semiconductor field-effect transistors (MOSFETs)) formed on the die substrate 1102. The transistors 1140 may include, for example, one or more source and/or drain (S/D) regions 1120, a gate 1122 to control current flow between the S/D regions 1120, and one or more S/D contacts 1124 to route electrical signals to/from the S/D regions 1120.

The gate 1122 may be formed of at least two layers, a gate dielectric, and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1140 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1140 along the source-channel-drain direction, the gate electrode may comprise a U-shaped structure that includes a bottom portion substantially parallel to the surface of the die substrate 1102 and two sidewall portions that are substantially perpendicular to the top surface of the die substrate 1102. In other embodiments, at least one of the metal layers that form the gate electrode may simply be a planar layer that is substantially parallel to the top surface of the die substrate 1102 and does not include sidewall portions substantially perpendicular to the top surface of the die substrate 1102. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 1120 may be formed within the die substrate 1102 adjacent to the gate 1122 of individual transistors 1140. The S/D regions 1120 may be formed using an implantation/diffusion process or an etching/deposition process, for example. In the former process, dopants such as boron, aluminum, antimony, phosphorous, or arsenic may be ion-implanted into the die substrate 1102 to form the S/D regions 1120. An annealing process that activates the dopants and causes them to diffuse farther into the die substrate 1102 may follow the ion-implantation process. In the latter process, the die substrate 1102 may first be etched to form recesses at the locations of the S/D regions 1120. An epitaxial deposition process may then be conducted to fill the recesses with material that is used to fabricate the S/D regions 1120. In some implementations, the S/D regions 1120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1120 may be formed using one or more alternate semiconductor materials such as germanium or a group III-V material or alloy. In further embodiments, one or more layers of metal and/or metal alloys may be used to form the S/D regions 1120.

Electrical signals, such as power and/or input/output (I/O) signals, may be routed to and/or from the devices (e.g., transistors 1140) of the device layer 1104 through one or more interconnect layers disposed on the device layer 1104 (illustrated in FIG. 11 as interconnect layers 1106-1110). For example, electrically conductive features of the device layer 1104 (e.g., the gate 1122 and the S/D contacts 1124) may be electrically coupled with the interconnect structures 1128 of the interconnect layers 1106-1110. The one or more interconnect layers 1106-1110 may form a metallization stack (also referred to as an “ILD stack”) 1119 of the integrated circuit 1100.

The interconnect structures 1128 may be arranged within the interconnect layers 1106-1110 to route electrical signals according to a wide variety of designs; in particular, the arrangement is not limited to the particular configuration of interconnect structures 1128 depicted in FIG. 11. Although a particular number of interconnect layers 1106-1110 is depicted in FIG. 11, embodiments of the present disclosure include integrated circuits having more or fewer interconnect layers than depicted.

In some embodiments, the interconnect structures 1128 may include lines 1128a and/or vias 1128b filled with an electrically conductive material such as a metal. The lines 1128a may be arranged to route electrical signals in a direction of a plane that is substantially parallel with a surface of the die substrate 1102 upon which the device layer 1104 is formed. For example, the lines 1128a may route electrical signals in a direction in and out of the page and/or in a direction across the page. The vias 1128b may be arranged to route electrical signals in a direction of a plane that is substantially perpendicular to the surface of the die substrate 1102 upon which the device layer 1104 is formed. In some embodiments, the vias 1128b may electrically couple lines 1128a of different interconnect layers 1106-1110 together.

The interconnect layers 1106-1110 may include a dielectric material 1126 disposed between the interconnect structures 1128, as shown in FIG. 11. In some embodiments, dielectric material 1126 disposed between the interconnect structures 1128 in different ones of the interconnect layers 1106-1110 may have different compositions; in other embodiments, the composition of the dielectric material 1126 between different interconnect layers 1106-1110 may be the same. The device layer 1104 may include a dielectric material 1126 disposed between the transistors 1140 and a bottom layer of the metallization stack as well. The dielectric material 1126 included in the device layer 1104 may have a different composition than the dielectric material 1126 included in the interconnect layers 1106-1110; in other embodiments, the composition of the dielectric material 1126 in the device layer 1104 may be the same as a dielectric material 1126 included in any one of the interconnect layers 1106-1110.

A first interconnect layer 1106 (referred to as Metal 1 or “M1”) may be formed directly on the device layer 1104. In some embodiments, the first interconnect layer 1106 may include lines 1128a and/or vias 1128b, as shown. The lines 1128a of the first interconnect layer 1106 may be coupled with contacts (e.g., the S/D contacts 1124) of the device layer 1104. The vias 1128b of the first interconnect layer 1106 may be coupled with the lines 1128a of a second interconnect layer 1108.

The second interconnect layer 1108 (referred to as Metal 2 or “M2”) may be formed directly on the first interconnect layer 1106. In some embodiments, the second interconnect layer 1108 may include via 1128b to couple the lines 1128a/b of the second interconnect layer 1108 with the lines 1128a of a third interconnect layer 1110. Although the lines 1128a and the vias 1128b are structurally delineated with a line within individual interconnect layers for the sake of clarity, the lines 1128a and the vias 1128b may be structurally and/or materially contiguous (e.g., simultaneously filled during a dual-damascene process) in some embodiments.

The third interconnect layer 1110 (referred to as Metal 3 or “M3”) (and additional interconnect layers, as desired) may be formed in succession on the second interconnect layer 1108 according to similar techniques and configurations described in connection with the second interconnect layer 1108 or the first interconnect layer 1106. In some embodiments, the interconnect layers that are “higher up” in the metallization stack 1119 in the integrated circuit 1100 (i.e., farther away from the device layer 1104) may be thicker that the interconnect layers that are lower in the metallization stack 1119, with lines 1128a and vias 1128b in the higher interconnect layers being thicker than those in the lower interconnect layers.

The integrated circuit 1100 may include a solder resist material 1134 (e.g., polyimide or similar material) and one or more conductive contacts 1136 formed on the interconnect layers 1106-1110. In FIG. 11, the conductive contacts 1136 are illustrated as taking the form of bond pads. The conductive contacts 1136 may be electrically coupled with the interconnect structures 1128 and configured to route the electrical signals of the transistor(s) 1140 to external devices. For example, solder bonds may be formed on the one or more conductive contacts 1136 to mechanically and/or electrically couple an integrated circuit die including the integrated circuit 1100 with another component (e.g., a printed circuit board). The integrated circuit 1100 may include additional or alternate structures to route the electrical signals from the interconnect layers 1106-1110; for example, the conductive contacts 1136 may include other analogous features (e.g., posts) that route the electrical signals to external components.

In some embodiments in which the integrated circuit 1100 is a double-sided die, the integrated circuit 1100 may include another metallization stack (not shown) on the opposite side of the device layer(s) 1104. This metallization stack may include multiple interconnect layers as discussed above with reference to the interconnect layers 1106-1110, to provide electrically conductive paths (e.g., including conductive lines and vias) between the device layer(s) 1104 and additional conductive contacts (not shown) on the opposite side of the integrated circuit 1100 from the conductive contacts 1136.

In other embodiments in which the integrated circuit 1100 is a double-sided die, the integrated circuit 1100 may include one or more through-silicon vias (TSVs) through the die substrate 1102; these TSVs may make contact with the device layer(s) 1104, and may provide electrically conductive paths between the device layer(s) 1104 and additional conductive contacts (not shown) on the opposite side of the integrated circuit 1100 from the conductive contacts 1136. In some embodiments, TSVs extending through the substrate can be used for routing power and ground signals from conductive contacts on the opposite side of the integrated circuit 1100 from the conductive contacts 1136 to the transistors 1140 and any other components integrated into the die of the integrated circuit 1100, and the metallization stack 1119 can be used to route I/O signals from the conductive contacts 1136 to transistors 1140 and any other components integrated into the die of the integrated circuit 1100.

Multiple integrated circuits 1100 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

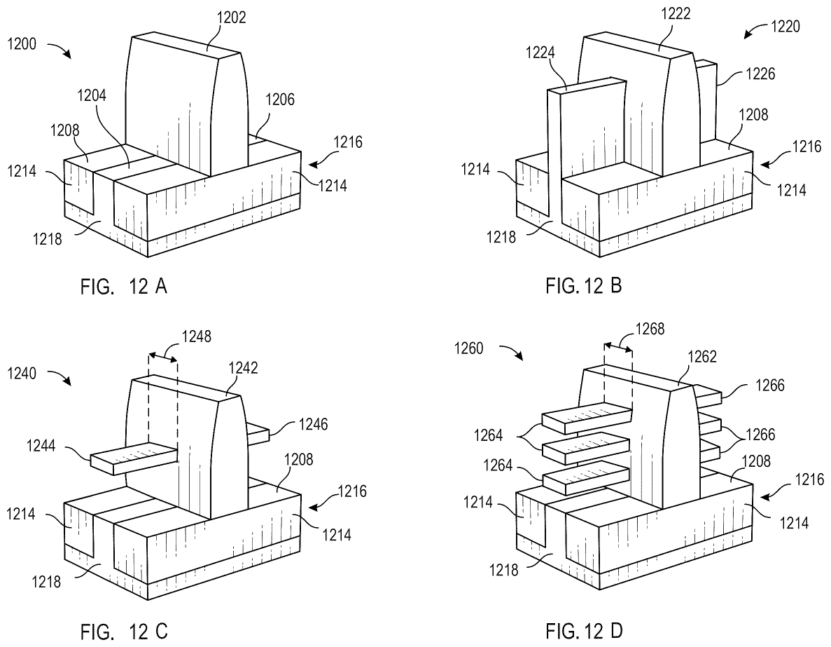

FIGS. 12A-12D are simplified perspective views of example planar, FinFET, gate-all-around, and stacked gate-all-around transistors. The transistors illustrated in FIGS. 12A-12D are formed on a substrate 1216 having a surface 1208. Isolation regions 1214 separate the source and drain regions of the transistors from other transistors and from a bulk region 1218 of the substrate 1216.

FIG. 12A is a perspective view of an example planar transistor 1200 comprising a gate 1202 that controls current flow between a source region 1204 and a drain region 1206. The transistor 1200 is planar in that the source region 1204 and the drain region 1206 are planar with respect to the substrate surface 1208.

FIG. 12B is a perspective view of an example FinFET transistor 1220 comprising a gate 1222 that controls current flow between a source region 1224 and a drain region 1226. The transistor 1220 is non-planar in that the source region 1224 and the drain region 1226 comprise “fins” that extend upwards from the substrate surface 1208. As the gate 1222 encompasses three sides of the semiconductor fin that extends from the source region 1224 to the drain region 1226, the transistor 1220 can be considered a tri-gate transistor. FIG. 12B illustrates one S/D fin extending through the gate 1222, but multiple S/D fins can extend through the gate of a FinFET transistor.

FIG. 12C is a perspective view of a gate-all-around (GAA) transistor 1240 comprising a gate 1242 that controls current flow between a source region 1244 and a drain region 1246. The transistor 1240 is non-planar in that the source region 1244 and the drain region 1246 are elevated from the substrate surface 1208.

FIG. 12D is a perspective view of a GAA transistor 1260 comprising a gate 1262 that controls current flow between multiple elevated source regions 1264 and multiple elevated drain regions 1266. The transistor 1260 is a stacked GAA transistor as the gate controls the flow of current between multiple elevated S/D regions stacked on top of each other. The transistors 1240 and 1260 are considered gate-all-around transistors as the gates encompass all sides of the semiconductor portions that extend from the source regions to the drain regions. The transistors 1240 and 1260 can alternatively be referred to as nanowire, nanosheet, or nanoribbon transistors depending on the width (e.g., widths 1248 and 1268 of transistors 1240 and 1260, respectively) of the semiconductor portions extending through the gate.

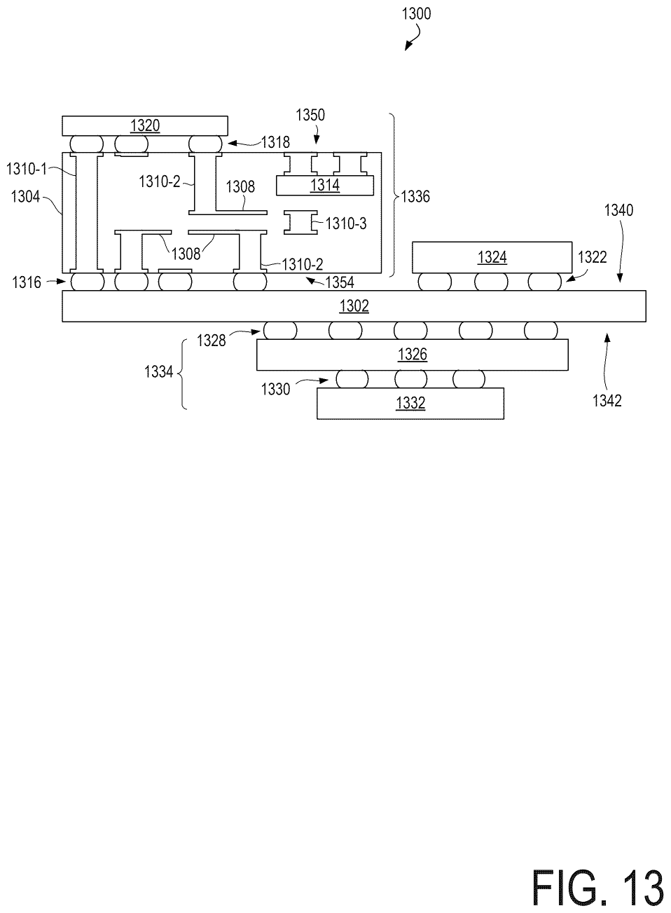

FIG. 13 is a cross-sectional side view of a microelectronic assembly 1300 that may include any of the embodiments disclosed herein. The microelectronic assembly 1300 includes multiple integrated circuit components disposed on a circuit board 1302 (which may be a motherboard, system board, mainboard, etc.). The microelectronic assembly 1300 may include components disposed on a first face 1340 of the circuit board 1302 and an opposing second face 1342 of the circuit board 1302; generally, components may be disposed on one or both faces 1340 and 1342.

In some embodiments, the circuit board 1302 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1302. In other embodiments, the circuit board 1302 may be a non-PCB substrate. The microelectronic assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1336 may include an integrated circuit component 1320 coupled to an interposer 1304 by coupling components 1318. The coupling components 1318 may take any suitable form for the application, such as the forms discussed above with reference to the coupling components 1316. Although a single integrated circuit component 1320 is shown in FIG. 13, multiple integrated circuit components may be coupled to the interposer 1304; indeed, additional interposers may be coupled to the interposer 1304. The interposer 1304 may provide an intervening substrate used to bridge the circuit board 1302 and the integrated circuit component 1320.

The integrated circuit component 1320 may be a packaged or unpackaged integrated circuit component that includes one or more integrated circuit dies (e.g., the die 1002 of FIG. 10, the integrated circuit 1100 of FIG. 11) and/or one or more other suitable components.

The unpackaged integrated circuit component 1320 comprises solder bumps attached to contacts on the die. The solder bumps allow the die to be directly attached to the interposer 1304. In embodiments where the integrated circuit component 1320 comprises multiple integrated circuit die, the die can be of the same type (a homogeneous multi-die integrated circuit component) or of two or more different types (a heterogeneous multi-die integrated circuit component). In addition to comprising one or more processor units, the integrated circuit component 1320 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1304 may spread connections to a wider pitch or reroute a connection to a different connection. For example, the interposer 1304 may couple the integrated circuit component 1320 to a set of ball grid array (BGA) conductive contacts of the coupling components 1316 for coupling to the circuit board 1302. In the embodiment illustrated in FIG. 13, the integrated circuit component 1320 and the circuit board 1302 are attached to opposing sides of the interposer 1304; in other embodiments, the integrated circuit component 1320 and the circuit board 1302 may be attached to a same side of the interposer 1304. In some embodiments, three or more components may be interconnected by way of the interposer 1304.

In some embodiments, the interposer 1304 may be formed as a PCB, including multiple metal layers separated from one another by layers of dielectric material and interconnected by electrically conductive vias. In some embodiments, the interposer 1304 may be formed of an epoxy resin, a fiberglass-reinforced epoxy resin, an epoxy resin with inorganic fillers, a ceramic material, or a polymer material such as polyimide. In some embodiments, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through hole vias 1310-1 (that extend from a first face 1350 of the interposer 1304 to a second face 1354 of the interposer 1304), blind vias 1310-2 (that extend from the first or second faces 1350 or 1354 of the interposer 1304 to an internal metal layer), and buried vias 1310-3 (that connect internal metal layers).

In some embodiments, the interposer 1304 can comprise a silicon interposer. Through-silicon vias (TSV) extending through the silicon interposer can connect connections on the first face of a silicon interposer to an opposing second face of the silicon interposer. In some embodiments, an interposer 1304 comprising a silicon interposer can further comprise one or more routing layers to route connections on a first face of the interposer 1304 to an opposing second face of the interposer 1304.

The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The integrated circuit assembly 1300 may include an integrated circuit component 1324 coupled to the first face 1340 of the circuit board 1302 by coupling components 1322. The coupling components 1322 may take the form of any of the embodiments discussed above with reference to the coupling components 1316, and the integrated circuit component 1324 may take the form of any of the embodiments discussed above with reference to the integrated circuit component 1320.

The integrated circuit assembly 1300 illustrated in FIG. 13 includes a package-on-package structure 1334 coupled to the second face 1342 of the circuit board 1302 by coupling components 1328. The package-on-package structure 1334 may include an integrated circuit component 1326 and an integrated circuit component 1332 coupled together by coupling components 1330 such that the integrated circuit component 1326 is disposed between the circuit board 1302 and the integrated circuit component 1332. The coupling components 1328 and 1330 may take the form of any of the embodiments of the coupling components 1316 discussed above, and the integrated circuit components 1326 and 1332 may take the form of any of the embodiments of the integrated circuit component 1320 discussed above. The package-on-package structure 1334 may be configured in accordance with any of the package-on-package structures known in the art.

FIG. 14 is a block diagram of an example electrical device 1400 that may include one or more of the embodiments disclosed herein. For example, any suitable ones of the components of the electrical device 1400 may include one or more of the disclosed embodiments, semiconductor assemblies, package assemblies, microelectronic assemblies 1300, integrated circuit components 1320, integrated circuits 1100, integrated circuit dies 1002, or structures disclosed herein. A number of components are illustrated in FIG. 14 as included in the electrical device 1400, but any one or more of these components may be omitted or duplicated, as suitable for the application. In some embodiments, some or all the components included in the electrical device 1400 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1400 may not include one or more of the components illustrated in FIG. 14, but the electrical device 1400 may include interface circuitry for coupling to the one or more components. For example, the electrical device 1400 may not include a display device 1406, but may include display device interface circuitry (e.g., a connector and driver circuitry) to which a display device 1406 may be coupled. In another set of examples, the electrical device 1400 may not include an audio input device 1424 or an audio output device 1408, but may include audio input or output device interface circuitry (e.g., connectors and supporting circuitry) to which an audio input device 1424 or audio output device 1408 may be coupled.

The electrical device 1400 may include one or more processor units 1402 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1402 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1400 may include a memory 1404, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1404 may include memory that is located on the same integrated circuit die as the processor unit 1402. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1400 can comprise one or more processor units 1402 that are heterogeneous or asymmetric to another processor unit 1402 in the electrical device 1400. There can be a variety of differences between the processor units 1402 in a system in terms of a spectrum of metrics of merit including architectural, microarchitectural, thermal, power consumption characteristics, and the like. These differences can effectively manifest themselves as asymmetry and heterogeneity among the processor units 1402 in the electrical device 1400.

In some embodiments, the electrical device 1400 may include a communication component 1412 (e.g., one or more communication components). For example, the communication component 1412 can manage wireless communications for the transfer of data to and from the electrical device 1400. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1412 may operate in accordance with other wireless protocols in other embodiments. The electrical device 1400 may include an antenna 1422 to facilitate wireless communications and/or to receive other wireless communications (such as AM or FM radio transmissions).

In some embodiments, the communication component 1412 may manage wired communications, such as electrical, optical, or any other suitable communication protocols (e.g., IEEE 802.3 Ethernet standards). As noted above, the communication component 1412 may include multiple communication components. For instance, a first communication component 1412 may be dedicated to shorter-range wireless communications such as Wi-Fi or Bluetooth, and a second communication component 1412 may be dedicated to longer-range wireless communications such as global positioning system (GPS), EDGE, GPRS, CDMA, WiMAX, LTE, EV-DO, or others. In some embodiments, a first communication component 1412 may be dedicated to wireless communications, and a second communication component 1412 may be dedicated to wired communications.

The electrical device 1400 may include power supply such as a battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display device 1406 (or corresponding interface circuitry, as discussed above). The display device 1406 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any embedded or wired or wirelessly connected external device that generates an audible indicator, such speakers, headsets, or earbuds.

The electrical device 1400 may include an audio input device 1424 (or corresponding interface circuitry, as discussed above). The audio input device 1424 may include any embedded or wired or wirelessly connected device that generates a signal representative of a sound, such as microphones, microphone arrays, or digital instruments (e.g., instruments having a musical instrument digital interface (MIDI) output). The electrical device 1400 may include a Global Navigation Satellite System (GNSS) device 1418 (or corresponding interface circuitry, as discussed above), such as a Global Positioning System (GPS) device. The GNSS device 1418 may be in communication with a satellite-based system and may determine a geolocation of the electrical device 1400 based on information received from one or more GNSS satellites, as known in the art.

The electrical device 1400 may include another output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include another input device 1420 (or corresponding interface circuitry, as discussed above). Examples of the other input device 1420 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1400 may be any other electronic device that processes data. In some embodiments, the electrical device 1400 may comprise multiple discrete physical components. Given the range of devices that the electrical device 1400 can be manifested as in various embodiments, in some embodiments, the electrical device 1400 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

Similarly, the word “overlaid” is used herein to denote a spatial relationship, being the past tense of overlay, to have been spread across, or superimposed on an object. Overlaid does not imply any particular procedure for placement. If a first layer is overlaid on a second layer, the first layer is also “located on” the second layer, as defined above.

Terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (also shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus, comprising: a first die comprising a static random-access memory (SRAM) periphery circuitry and a first memory sub-bank; wherein the first die includes a first surface defined by a first insulating material having exposed therein a plurality of first conductive contacts, multiple of the first conductive contacts are arranged around two adjacent edges of the first memory sub-bank; and a second die on the first die, the second die comprising a second memory sub-bank positioned over the first memory sub-bank, wherein the second die includes a second surface defined by a second insulating material; wherein the plurality of first conductive contacts is directly attached to a respective plurality of second conductive contacts exposed in the second insulating material, and the first insulating material is directly attached to the second insulating material.

Example 2 includes the subject matter of Example 1, wherein the multiple of the first conductive contacts are to route control and data lines from the first die to the second die.

Example 3 includes the subject matter of Example 1, wherein a remainder of the first conductive contacts are arranged on a third edge of the first memory sub-bank and are to route power and ground from the first die to the second die.

Example 4 includes the subject matter of Example 1, wherein some of the first conductive contacts are attached to through silicon vias (TSVs) with a minimum dimension less than 10 microns+/−20%.

Example 5 includes the subject matter of Example 4, wherein the TSVs comprise one or more of tungsten, titanium, tantalum, molybdenum, magnesium, and cobalt.

Example 6 includes the subject matter of Example 1, wherein some of the first conductive contacts are attached to through silicon vias (TSVs) with a minimum dimension greater than 1 micron+/−20%.

Example 7 includes the subject matter of Example 1, wherein a metal stack is defined as multiple layers of metal interleaved with an insulating material, and the metal stack in the second die is smaller than the metal stack in the first die.

Example 8 includes the subject matter of Example 1, wherein a metal stack in the first die comprises at least one layer of metal with a thickness greater than 500 nanometers+/−20%, and all layers of metal in the metal stack in the second die are less than 500 nanometers+/−20%.

Example 9 includes the subject matter of Example 1, wherein the SRAM periphery circuitry comprises a control and pre-decode circuitry, a post-decode circuitry, and a bit-line circuitry.

Example 10 includes the subject matter of Example 1, wherein the first insulating material and the second insulating material comprise a dielectric material or ultra-low dielectric constant material.

Example 11 includes the subject matter of Example 1, wherein the first conductive contacts and the second conductive contacts comprise a metal.

Example 12 includes the subject matter of Example 1, wherein the first conductive contacts and the second conductive contacts comprise copper.

Example 13 is an apparatus, comprising: a static random-access memory (SRAM) comprising a memory bank and periphery circuitry, wherein the periphery circuitry includes a control and pre-decode circuit, a post-decode circuit, a bit-line circuit, and the memory bank includes a first memory sub-bank and a second memory sub-bank; a first die comprising the first memory sub-bank, the control and pre-decode circuit, the bit-line circuit, and a first part of the post-decode circuit; wherein the first die includes a first surface defined by a first insulating material having exposed therein a plurality of first conductive contacts, multiple of the first conductive contacts are arranged around two adjacent edges of the first memory sub-bank; and a second die on the first die, the second die comprising a second memory sub-bank positioned over the first memory sub-bank, and a second part of the post-decode circuit positioned over the first part of the post-decode circuit, wherein the second die includes a second surface defined by a second insulating material; wherein the plurality of first conductive contacts is directly attached to a respective plurality of second conductive contacts exposed in the second insulating material, and the first insulating material is directly attached to the second insulating material.

Example 14 includes the subject matter of Example 13, wherein the multiple of the first conductive contacts are to route control and data lines from the first die to the second die.

Example 15 includes the subject matter of Example 14, wherein a remainder of the first conductive contacts are arranged on a third edge of the first memory sub-bank and are to route power and ground from the first die to the second die.

Example 16 includes the subject matter of Example 15, further comprising solder bumps on a bottom surface of the first die.

Example 17 is a system that includes the subject matter of Example 16, further comprising: a printed circuit board attached to the solder bumps; and a processor architecture circuit attached to the printed circuit board to communicate with the apparatus.

Example 18 includes the subject matter of Example 17, further comprising: a package-on-interposer structure with an integrated circuit component attached thereto; and wherein the package-on-interposer structure is attached to the printed circuit board.

Example 19 is a method for a three-dimensional memory, comprising: manufacturing a top die up to its final metal layer, wherein manufacturing the top die includes creating a hybrid bonding (HB) surface over the final metal layer, the HB surface including a first dielectric material with conductive pads therein; manufacturing a bottom die to include periphery logic for a static random access memory (SRAM), wherein manufacturing the bottom die includes creating one or more first through silicon vias (TSVs), depositing remaining metal layers to accommodate keep out zones for middle TSVs, overlaying layers of a second dielectric material and metal layers up to a top surface of the second dielectric material with conductive contacts therein; bonding the top die to the bottom die such that conductive pads are bonded directly to conductive contacts and the dielectric material is bonded directly to the dielectric material.

Example 20 includes the subject matter of Example 19, wherein manufacturing the bottom die further includes creating first through silicon vias (first TSVs) and middle through silicon vias (middle TSVs), with the middle TSVs having a diameter in a range of 300 microns+/−20%, and the first TSVs having a diameter of 100 microns+/−20%.

What is claimed is:

1. An apparatus, comprising:
a first die comprising a static random-access memory (SRAM) periphery circuitry and a first memory sub-bank;
wherein the first die includes a first surface defined by a first insulating material having exposed therein a plurality of first conductive contacts, multiple of the first conductive contacts are arranged around two adjacent edges of the first memory sub-bank; and
a second die on the first die, the second die comprising a second memory sub-bank positioned over the first memory sub-bank, wherein the second die includes a second surface defined by a second insulating material;
wherein the plurality of first conductive contacts is directly attached to a respective plurality of second conductive contacts exposed in the second insulating material, and the first insulating material is directly attached to the second insulating material.

2. The apparatus of claim 1, wherein the multiple of the first conductive contacts are to route control and data lines from the first die to the second die.

3. The apparatus of claim 1, wherein a remainder of the first conductive contacts are arranged on a third edge of the first memory sub-bank and are to route power and ground from the first die to the second die.

4. The apparatus of claim 1, wherein some of the first conductive contacts are attached to through silicon vias (TSVs) with a minimum dimension less than 10 microns+/−20%.

5. The apparatus of claim 4, wherein the TSVs comprise one or more of tungsten, titanium, tantalum, molybdenum, magnesium, and cobalt.

6. The apparatus of claim 1, wherein some of the first conductive contacts are attached to through silicon vias (TSVs) with a minimum dimension greater than 1 micron+/−20%.

7. The apparatus of claim 1, wherein a metal stack is defined as multiple layers of metal interleaved with an insulating material, and the metal stack in the second die is smaller than the metal stack in the first die.

8. The apparatus of claim 1, wherein a metal stack in the first die comprises at least one layer of metal with a thickness greater than 500 nanometers+/−20%, and all layers of metal in the metal stack in the second die are less than 500 nanometers+/−20%.

9. The apparatus of claim 1, wherein the SRAM periphery circuitry comprises a control and pre-decode circuitry, a post-decode circuitry, and a bit-line circuitry.

10. The apparatus of claim 1, wherein the first insulating material and the second insulating material comprise a dielectric material or ultra-low dielectric constant material.

11. The apparatus of claim 1, wherein the first conductive contacts and the second conductive contacts comprise a metal.

12. The apparatus of claim 1, wherein the first conductive contacts and the second conductive contacts comprise copper.

13. An apparatus, comprising:
a static random-access memory (SRAM) comprising a memory bank and periphery circuitry, wherein the periphery circuitry includes a control and pre-decode circuit, a post-decode circuit, a bit-line circuit, and the memory bank includes a first memory sub-bank and a second memory sub-bank;
a first die comprising the first memory sub-bank, the control and pre-decode circuit, the bit-line circuit, and a first part of the post-decode circuit;
wherein the first die includes a first surface defined by a first insulating material having exposed therein a plurality of first conductive contacts, multiple of the first conductive contacts are arranged around two adjacent edges of the first memory sub-bank; and
a second die on the first die, the second die comprising a second memory sub-bank positioned over the first memory sub-bank, and a second part of the post-decode circuit positioned over the first part of the post-decode circuit, wherein the second die includes a second surface defined by a second insulating material;
wherein the plurality of first conductive contacts is directly attached to a respective plurality of second conductive contacts exposed in the second insulating material, and the first insulating material is directly attached to the second insulating material.

14. The apparatus of claim 13, wherein the multiple of the first conductive contacts are to route control and data lines from the first die to the second die.

15. The apparatus of claim 14, wherein a remainder of the first conductive contacts are arranged on a third edge of the first memory sub-bank and are to route power and ground from the first die to the second die.

16. The apparatus of claim 15, further comprising solder bumps on a bottom surface of the first die.

17. A system comprising the apparatus of claim 16, and further comprising:
a printed circuit board attached to the solder bumps; and
a processor architecture circuit attached to the printed circuit board to communicate with the apparatus.

18. The system of claim 17, further comprising:
a package-on-interposer structure with an integrated circuit component attached thereto; and
wherein the package-on-interposer structure is attached to the printed circuit board.

19. A method for a three-dimensional memory, comprising:
manufacturing a top die up to its final metal layer, wherein manufacturing the top die includes creating a hybrid bonding (HB) surface over the final metal layer, the HB surface including a first dielectric material with conductive pads therein;
manufacturing a bottom die to include periphery logic for a static random access memory (SRAM), wherein manufacturing the bottom die includes creating one or more first through silicon vias (TSVs), depositing remaining metal layers to accommodate keep out zones for middle TSVs, overlaying layers of a second dielectric material and metal layers up to a top surface of the second dielectric material with conductive contacts therein;
bonding the top die to the bottom die such that conductive pads are bonded directly to conductive contacts and the dielectric material is bonded directly to the dielectric material.

20. The method of claim 19, wherein manufacturing the bottom die further includes creating first through silicon vias (first TSVs) and middle through silicon vias (middle TSVs), with the middle TSVs having a diameter in a range of 300 microns+/−20%, and the first TSVs having a diameter of 100 microns+/−20%.
